(19) United States
(12) Patent Application Publication
(10) Pub. No.: US 2016/0049401 A1
(43) Pub. Date: Feb. 18, 2016

(54) HYBRID CONTACTS FOR COMMONLY FABRICATED SEMICONDUCTOR DEVICES USING SAME METAL

(71) Applicant: GLOBALFOUNDRIES Inc., Grand Cayman (KY)

(72) Inventors: Min Gyu SUNG, Latham, NY (US); Hiroaki NIIMI, Cohoes, NY (US); Kwanyong LIM, Niskayuna, NY (US)

(73) Assignee: GLOBALFOUNDRIES INC., Grand Cayman (KY)

(21) Appl. No.: 14/459,005

(22) Filed: Aug. 13, 2014

(51) Int. Cl. H01L 27/092; H01L 29/66; H01L 21/28; H01L 21/8238; H01L 29/49; H01L 29/51; H01L 21/02; H01L 29/06; H01L 27/11; H01L 21/285

(52) U.S. Cl. CPC H01L 27/0924; H01L 27/1104; H01L 27/0922; H01L 29/6681; H01L 21/28088; H01L 21/28518; H01L 21/2855; H01L 21/28568; H01L 29/4975; H01L 29/517; H01L 21/0217; H01L 29/0649; H01L 21/823814; H01L 21/823835; H01L 21/823821; H01L 21/823871

(57) ABSTRACT

A non-planar semiconductor structure, for example, a dual FinFET structure, includes a n-type semiconductor device and a p-type semiconductor device. Metal-insulator-semiconductor (MIS) contacts provide electrical connection to the n-type device, and metal-semiconductor (MS) contacts provide electrical connection to the p-type device. The metal of both MIS and MS contacts is a same n-type work function metal. In one example, the semiconductor of the MIS contact includes epitaxial silicon germanium with a relatively low percentage of germanium, the insulator of the MIS contact includes titanium dioxide, the semiconductor for the MS contact includes silicon germanium with a relatively high percentage of germanium or pure germanium, and the metal for both contacts includes a n-type work function metal.

### BACKGROUND OF THE INVENTION

1. Technical Field

The present invention generally relates to contacts and contact formation for non-planar semiconductor devices. More specifically, the present invention relates to contacts for commonly fabricated n-type and p-type devices using a same metal.

2. Background Information

In conventional semiconductor device fabrication, for example, transistors, silicide is used to provide electrical conductance between the source or drain and the contact to the source or drain. Silicides typically used include nickel silicide and titanium silicide. However, each of those silicides has associated positive and negative aspects. For example, nickel silicide has low contact resistivity, but can develop defects under the sidewalls, which can lead to source/drain shorts and SRAM yield loss. As another example, titanium silicide will not generate the defect noted, but it will degrade device performance, particularly with p-type transistors, due to a relatively high contact resistivity.

Therefore, a need exists for improved contacts and contact formation in semiconductor devices.

### SUMMARY OF THE INVENTION

The shortcomings of the prior art are overcome and additional advantages are provided through the provision, in one aspect, of method of fabricating hybrid contacts with a same metal. The method includes providing a starting semiconductor structure, the structure including a semiconductor substrate, raised semiconductor structure(s) coupled to the substrate having region(s) for a n-type semiconductor device and region(s) for a p-type semiconductor device, the regions separated by isolation material, dummy gate structure(s) over each of the regions and a conformal layer of a spacer material over the starting structure. The method further includes creating a metal-insulator-semiconductor (MIS) contact for the n-type semiconductor device, and creating a metal-semiconductor (MS) contact for the p-type semiconductor device. The metal is a same metal as the MIS contact.

In accordance with another aspect, a semiconductor structure is provided. The structure includes n-type semiconductor device(s), p-type semiconductor device(s), a metal-insulator-semiconductor (MIS) contact for the n-type semiconductor device, and a metal-semiconductor (MS) contact for the p-type semiconductor device. The metal is a same metal as the contact for the n-type semiconductor device.

These, and other objects, features and advantages of this invention will become apparent from the following detailed description of the various aspects of the invention taken in conjunction with the accompanying drawings.

### BRIEF DESCRIPTION OF THE DRAWINGS

FIG. 1 is a cross-sectional view of one example of a starting non-planar semiconductor structure, the structure including a semiconductor substrate, raised semiconductor structure(s) coupled to the substrate having region(s) for a n-type semiconductor device and region(s) for a p-type semiconductor device, the n-type and p-type regions being separated by isolation material, dummy gate structure(s) over each of the regions and a conformal layer of a spacer material over the starting structure.

FIG. 2 depicts the non-planar structure of FIG. 1 after creating a lithographic stack over the structure.

FIG. 3 depicts the structure of FIG. 2 after lithography of the n-type device region, removal of the lithographic stack over the n-type device region and partially over the p-type device region, and removal of the spacer material over the n-type device region except for the dummy gate structures of the n-type device region, which reduces a height of the dummy gate structures of the n-type device region.

FIG. 4 depicts the structure of FIG. 3 after removal of the remaining lithographic stack over the p-type device region and creation of n-type epitaxy on the n-type device region.

FIG. 5 depicts the structure of FIG. 4 after the creation of silicide on the n-type epitaxy.

FIG. 6 depicts the structure of FIG. 5 after removal of the spacer material over the p-type device region, except for the spacer material on the dummy gate structures of the p-type device region, which reduces a height of the dummy gate structures of the p-type device region.

FIG. 7 depicts the structure of FIG. 6 after creation of p-type epitaxy on the p-type device region.

FIG. 8 depicts the structure of FIG. 7 after creation of a relatively think blanket conformal layer of a protective material over the structure.

FIG. 9 depicts the structure of FIG. 8 after creation of a blanket conformal layer of a first dielectric material over the layer of protective material.

FIG. 10 depicts the structure of FIG. 9 after planarization of the first dielectric layer, which also removes a top portion of the dummy gate structures, and removal of the remaining portion of the dummy gate structures, creating gate openings over both region types.

FIG. 11 depicts the structure of FIG. 10 after creating replacement gate structures, planarizing and creating a second layer of dielectric material over the planarized structure.

FIG. 12 depicts the structure of FIG. 11 after creating contact openings to the replacement gates, to the silicide on the n-type epitaxy and to the p-type epitaxy over the p-type device region.

FIG. 13 depicts the structure of FIG. 12 after filling all the contact openings with a n-type work function material and conductive material, creating contacts.

FIG. 14 depicts the structure of FIG. 4 after directional deposition of silicide over the structure.

FIG. 15 depicts the structure of FIG. 14 after removal of the spacer material over the p-type device region, except for the spacer material on the dummy gate structures of the p-type device region, which reduces a height of the dummy gate structures of the p-type device region, and leaving the silicide intact on the n-type device region.

FIG. 16 depicts the structure of FIG. 12 after filling all the contact openings with a single n-type work function metal.

### DETAILED DESCRIPTION OF THE INVENTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

Reference is made below to the drawings, which are not drawn to scale for ease of understanding, wherein the same reference numbers are used throughout different figures to designate the same or similar components.

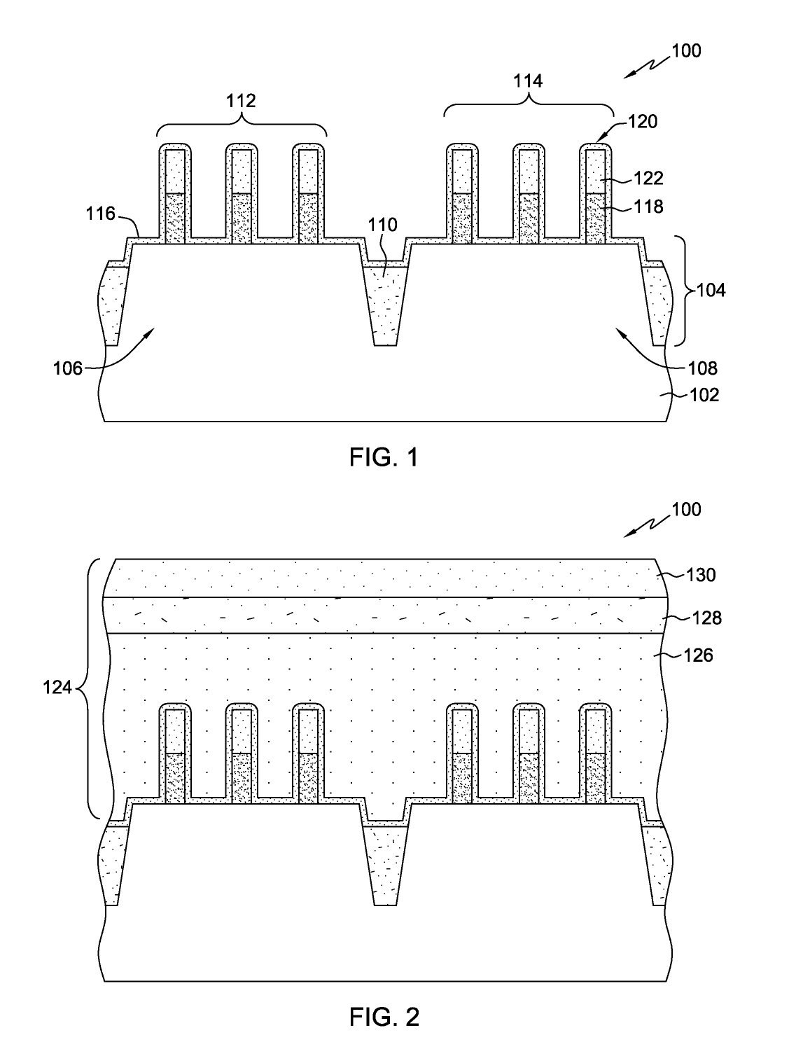

FIG. 1 is a cross-sectional view of one example of a starting non-planar semiconductor structure 100, the structure including a semiconductor substrate 102, raised semiconductor structure(s) (e.g., raised semiconductor structure 104) coupled to the substrate having region(s) 106 for a n-type semiconductor device and region(s) 108 for a p-type semiconductor device, the regions separated by isolation material 110, dummy gate structure(s) 112 and 114 over the n-type and p-type regions, respectively, and a conformal layer 116 of a spacer material over the structure.

In one example, substrate 102 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. Substrate 102 may in addition or instead include various isolations, dopings and/or device features. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof.

In one example, the raised structure(s) 104 may take the form of a “fin.” The raised structure(s) may be etched from a bulk substrate, and may include, for example, any of the materials listed above with respect to the substrate. Further, some or all of the raised structure(s) may include added impurities (e.g., by doping), making them n-type or p-type.

The structure further includes at least one gate structure 106 surrounding a portion of one or more of the raised structures. In one example, region 106 may be part of a n-type non-planar transistor, and region 108 may be part of a p-type non-planar transistor.

Isolation material 110 may be, for example, a shallow-trench isolation (STI) material, for example, an oxide (e.g., silicon dioxide). The dummy gate structures may include, for example, a lower section (for example, section 118 of dummy gate structure 120) of a dummy gate material (e.g., polycrystalline silicon), and an upper section 122 of a hard mask material (e.g., silicon nitride). The conformal layer 116 of spacer material may include, for example, a low-k spacer material having a dielectric constant value below about 6 to about 7 (the dielectric constant of silicon nitride), e.g., SiOCN (k=about 4.2 to about 4.4) or SiBCN (k=about 4.5 to about 5.5), or a nitride (e.g., silicon nitride).

The starting structure may be conventionally fabricated, for example, using conventional processes and techniques. However, it will be understood that the fabrication of the starting structure forms no part of the present invention. Further, although only a portion is shown for simplicity, it will be understood that, in practice, many such structures are typically included on the same bulk substrate.

FIG. 2 depicts the non-planar structure 100 of FIG. 1 after creating a lithographic stack 124 over the structure. The lithographic stack may include, for example, a bottom layer 126 of an organic planarization material. The organic planarization layer (OPL) may include, for example, a photo-sensitive organic polymer including a light-sensitive material that, when exposed to electromagnetic radiation, is chemically altered and thus configured to be removed using a development solvent. For example, the photo-sensitive organic polymer may be polyacrylate resin, epoxy resin, phenol resin, polyamide resin, polyimide resin, unsaturated polyester resin, polyphenylenether resin, polyphenylenesulfide resin, or benzocyclobutene (BCB). The lithographic stack may further include, for example, a middle layer 128 of an anti-reflective coating (ARC) material. The ARC layer focuses light to improve resolution during optical lithography. Finally, the lithographic stack may also include, for example, a top layer 130 of a lithographic blocking material, e.g., photo resist.

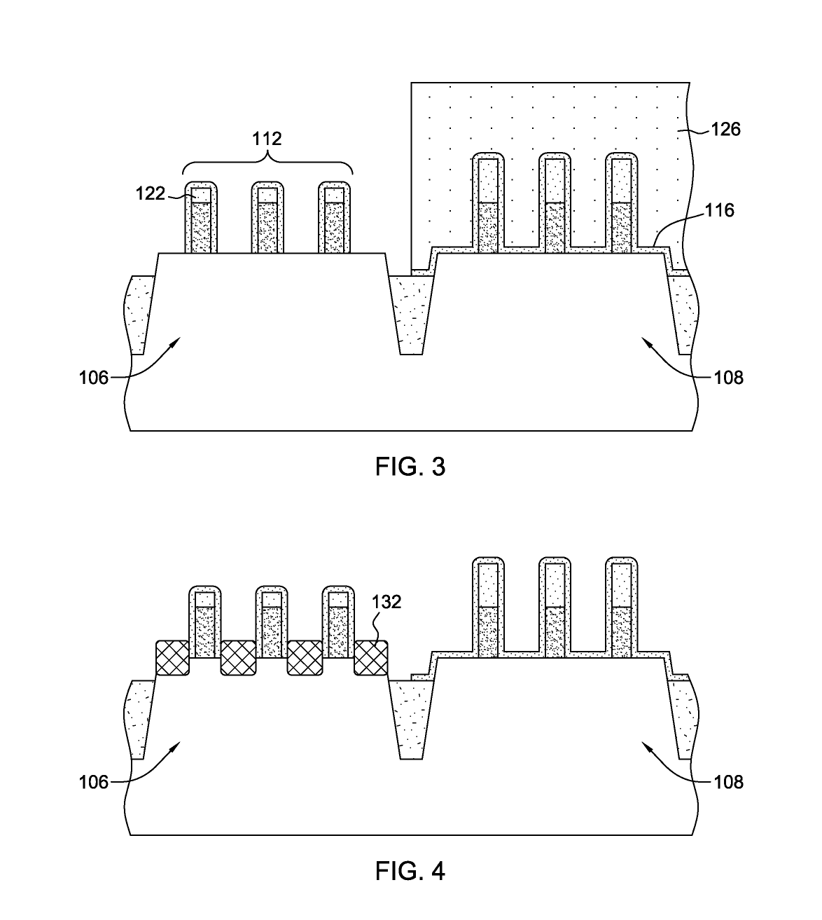

FIG. 3 depicts the structure of FIG. 2 after lithography of the n-type device region 106, removal of the lithographic stack 124 over the n-type device region and partially over the p-type device region 108, and removal of the spacer material 116 over the n-type device region except for the dummy gate structures 112 of the n-type device region, which reduces a height of the dummy gate structures of the n-type device region, by removing some of the upper section 122 of hard mask material.

During lithography of the n-type device region, the layer 130 of lithographic blocking material is removed over region 106, using, for example, tetramethyl ammonium hydroxide (TMAH). After lithography, the middle layer of ARC material may then be removed over the n-type region, using, for example, a wet etch, e.g., SCl(NH₄OH:H₂O₂:H₂O). This will also remove the top and middle layers of the lithographic stack over the p-type region 108. Removal of the layer 126 of OPL material over the n-type region may be accomplished using, for example, a wet reactive-ion etch (RIE) process, e.g., a plasma etch with N₂H₂. Selective removal of the conformal layer 116 of spacer material over the n-type region, may be accomplished using, for example, a dry RIE process, e.g., using one of CF₄, NF₃, CHF₃ and SF₆. Finally, the remaining layer 126 of OPL material may be removed (see FIG. 4) over the p-type region, for example, using the same process as used for the n-type region.

FIG. 4 depicts the structure of FIG. 3 after removal of the remaining lithographic stack over the p-type device region 108 and creation of n-type epitaxy 132 on the n-type device region. The n-type epitaxy 132 may include, for example, phosphorus-doped silicon (SiP), or silicon germanium (SiGe) with a relatively low percentage of germanium, e.g., less than about 25% germanium. Where the n-type epitaxy includes SiGe, the epitaxy may be created by, for example, growth using a chemical-vapor deposition process. In one example, SiCl₂H₂ and GeH₄ in hydrogen gas may be used a precursors for the silicon and germanium, respectively, and B₂H₆ and PH₃ may be used as doping sources. The temperature for growth may be, for example, above about 600° C. Where the n-type device includes a non-planar transistor, the n-type epitaxy may serve as source and drain.

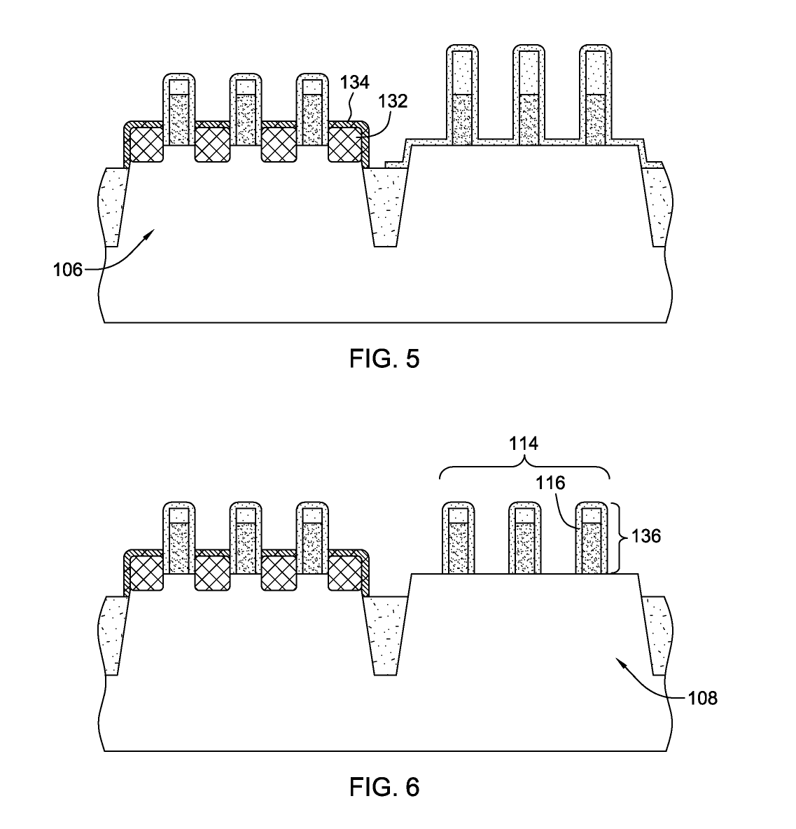

FIG. 5 depicts the structure of FIG. 4 after the creation of silicide 134 on the n-type epitaxy 132. Creating the silicide may be accomplished, for example, by selective growth. In one example, where the n-type epitaxy includes silicon germanium, titanium dioxide can be selectively grown thereon. In one specific example, Ti(OⁱPr)₄ may be used as a precursor, and the conditions may include a deposition pressure of about 3.0×10⁻² Torr to about 4.0×10⁻² Torr, a deposition temperature of about 300° C. to about 500° C. and deposition time of about 30 minutes to about 2 hours.

FIG. 6 depicts the structure of FIG. 5 after removal of the spacer material 116 over the p-type device region 108, except for the spacer material on the dummy gate structures 114 of the p-type device region, which reduces a height 136 of the dummy gate structures of the p-type device region, similar to removal of the spacer material over the n-type device region described with respect to FIG. 3. Between FIGS. 5 and 6, the lithographic process described with respect to FIGS. 2-3 is repeated for the p-type device region 108.

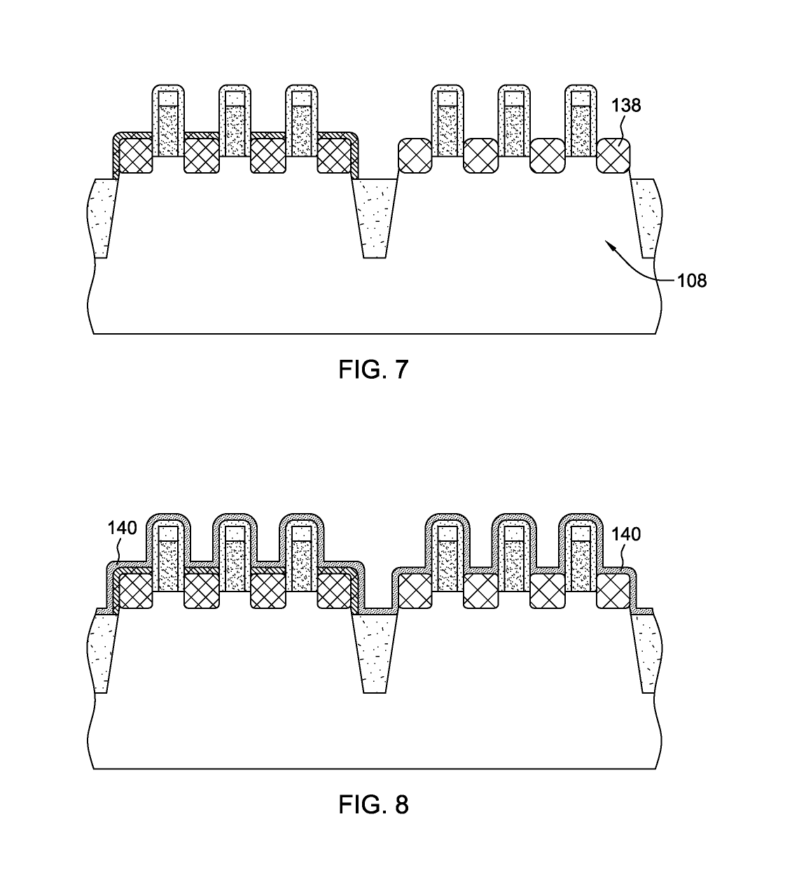

FIG. 7 depicts the structure of FIG. 6 after creation of p-type epitaxy 138 on the p-type device region 108. The p-type epitaxy 138 may include, for example, pure germanium, or silicon germanium with a relatively high percentage of germanium, e.g., above about 80% germanium. Where the p-type epitaxy includes SiGe, the epitaxy may be created by, for example, growth using a chemical-vapor deposition process. In one example, SiCl₂H₂ and GeH₄ in hydrogen gas may be used a precursors for the silicon and germanium, respectively, and B₂H₆ and PH₃ may be used as doping sources. The temperature for growth may be, for example, above about 600° C. Where the p-type device includes a non-planar transistor, the n-type epitaxy may serve as source and drain.

FIG. 8 depicts the structure of FIG. 7 after creation of a relatively thin blanket conformal layer 140 of a protective material over the structure. In one example, the protective material includes a nitride, e.g., silicon nitride, with a thickness of, for example, about 3 nm to about 5 nm. Creation of the layer of protective material may be accomplished using, for example, atomic layer deposition (ALD).

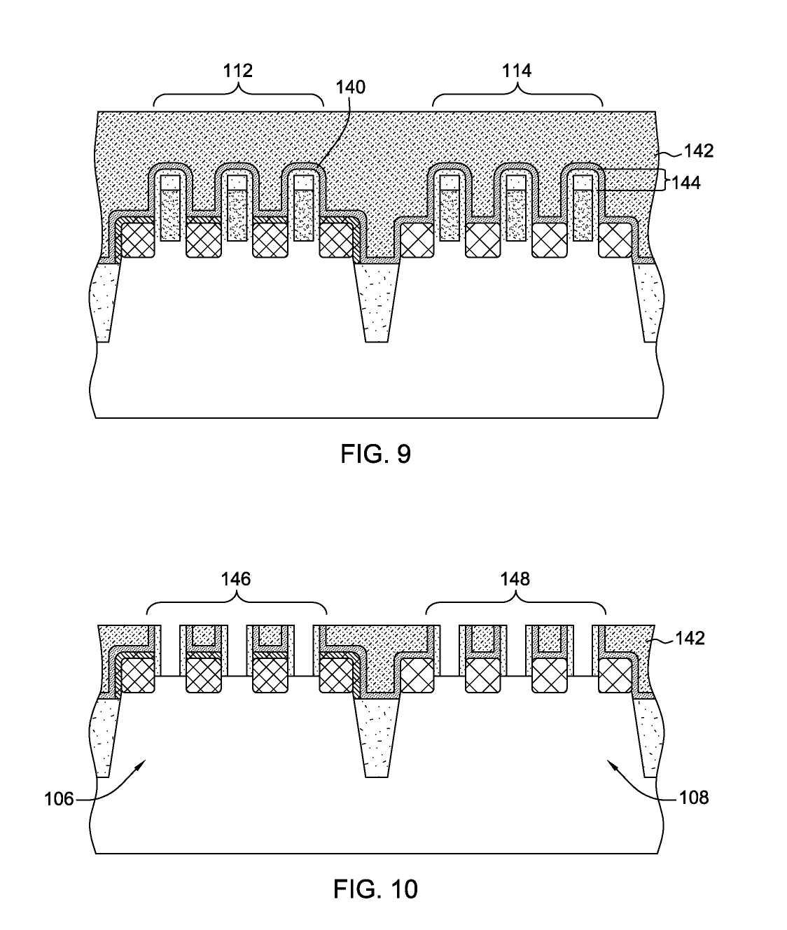

FIG. 9 depicts the structure of FIG. 8 after creation of a blanket conformal layer 142 of a first dielectric material over the layer of protective material 140. The first dielectric material may include, for example, an interlayer dielectric material, such as an oxide, e.g., silicon dioxide, which may be deposited, for example, using a CVD method.

FIG. 10 depicts the structure of FIG. 9 after planarization of the first dielectric layer 142, which also removes a top portion (144, FIG. 9) of dummy gate structures (112 and 114, FIG. 9), and removal of the remaining portion of the dummy gate structures, creating gate openings 146 and 148 over the n-type and p-type device regions 106 and 108, respectively. Planarization of the first dielectric layer may be accomplished using, for example, a chemical-mechanical polishing process. Removal of the dummy gate structures may be accomplished using, for example, buffered hydrofluoric acid (BHF) to remove silicon dioxide at a top of the dummy gate structure, followed by ammonia (NH₄OH) to remove polysilicon.

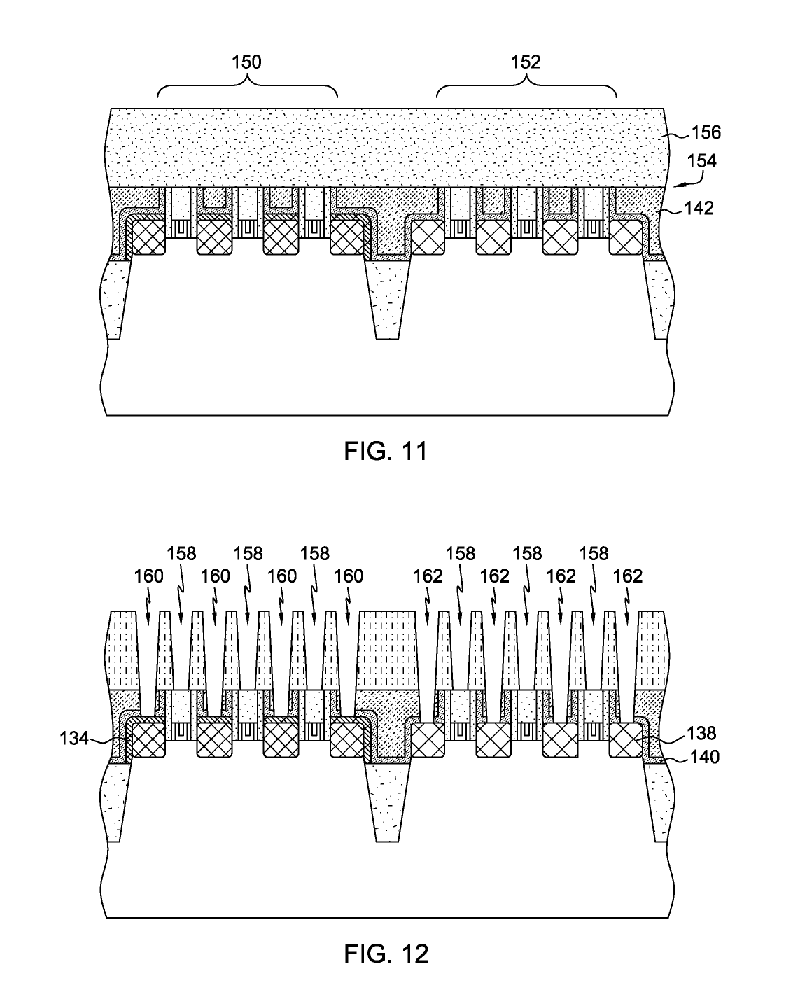

FIG. 11 depicts the structure of FIG. 10 after creating replacement gate structures 150 and 152, planarizing 154 and creating a second layer 156 of dielectric material over the planarized structure. The gate structures may be created, for example, using conventional techniques, the gate structures including, for example, one or more layers of one or more work function materials (e.g., work function metal), one or more conductive materials, for example, one or more metals (e.g., tungsten), and a protective cap, for example, a nitride (e.g., silicon nitride). The planarizing may be accomplished using, for example, a chemical-mechanical polishing process. The second layer of dielectric material may include, for example, an oxide which may be different from that of the first dielectric layer 142. The second dielectric layer may be created using, for example, plasma-enhanced tetraethylorthosilicate oxide (PETEOS).

FIG. 12 depicts the structure of FIG. 11 after creating contact openings 158 to the replacement gates, to the silicide 134 on the n-type epitaxy (openings 160) and to the p-type epitaxy 138 over the p-type device region (openings 162). The openings may be created, for example, using an etch selective to the two layers of dielectric material and the silicide (e.g., titanium dioxide). For example, where the silicide includes titanium dioxide, the etching stops on the titanium dioxide on the n-type device region 106. The thin layer of protective material 140 (e.g., silicon nitride) is gone during the etch of dielectric layers 142 and 156. As a result, the contact for the n-type device region lands on the silicide (e.g., titanium dioxide), while the contact for the p-type device region 108 lands on the p-type epitaxy (e.g., epitaxial silicon germanium).

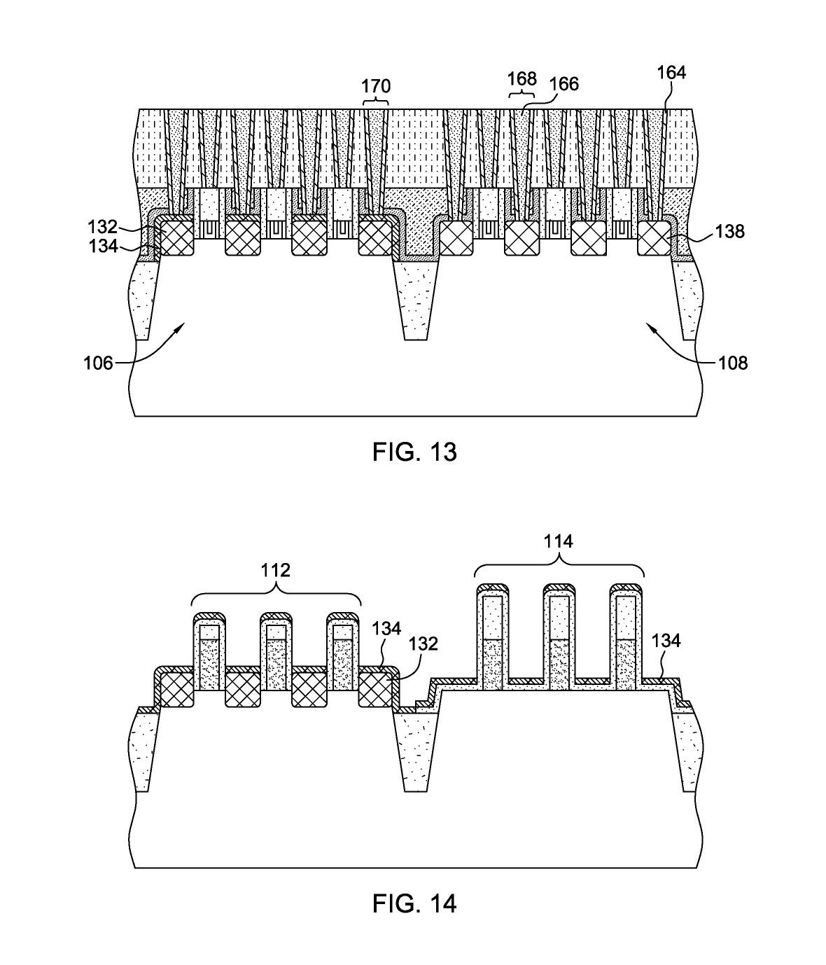

FIG. 13 depicts the structure of FIG. 12 after filling all the contact openings with a n-type work function material 164 and conductive material 166, creating contacts, e.g., contacts 168 and 170.

Contact 170 over the n-type device region 106 includes a metal-insulator-semiconductor (MIS) contact, where the n-type work function material includes a n-type work function metal (the “metal”), the “insulator” includes the silicide 134, and the “semiconductor” includes the n-type epitaxial material 132. Contact 168 over the p-type device region 108 includes a metal-semiconductor (MS) contact, the “metal” also including the n-type work function metal and the “semiconductor” including the p-type epitaxial material 138. Filling the contact openings with n-type work function material may be accomplished using, for example, an ALD or PVD method, while filling the openings with conductive material, for example, a metal (e.g., tungsten), may be accomplished using, for example, CVD with tungsten hexafluoride (WH₆) and silane gas (SiH₄).

FIG. 14 depicts the structure of FIG. 4 after directional deposition of silicide 134 over the structure. The directional deposition may be accomplished using, for example, a physical vapor deposition (PVD) method, which results in deposition of the silicide everywhere on the structure, except along vertical sections of the layer 116 of spacer material on dummy gate structures 112 and 114.

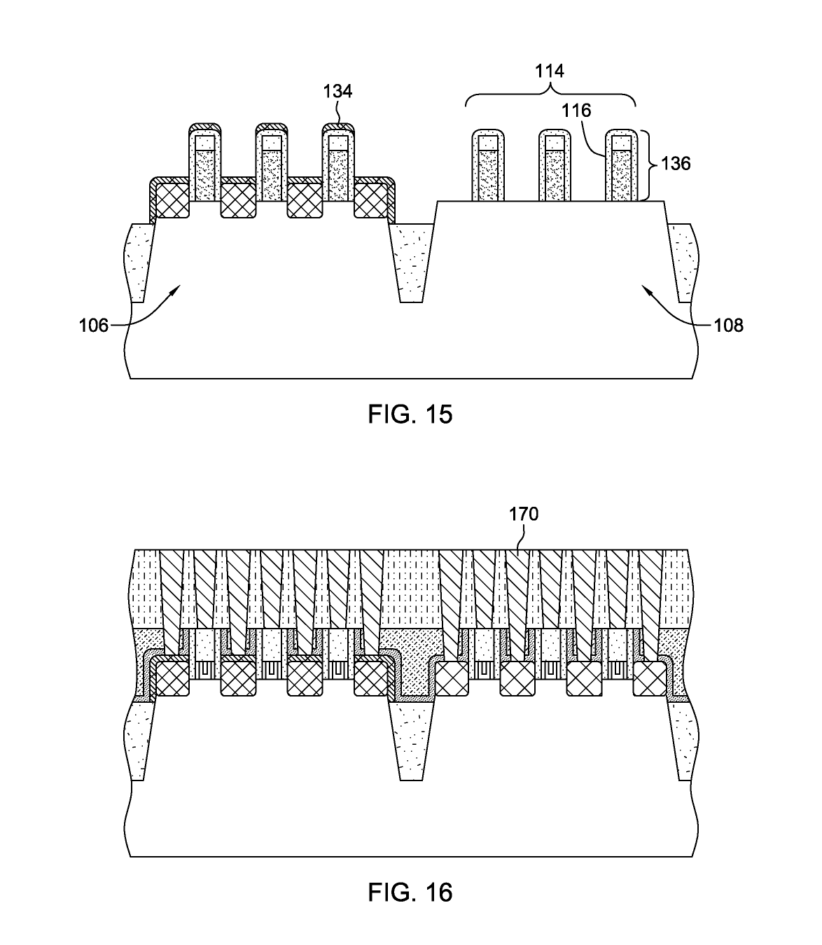

FIG. 15 depicts the structure of FIG. 14 after removal of the spacer material 116 over the p-type device region 108, except for the spacer material on the dummy gate structures 114 of the p-type device region, which reduces a height 136 of the dummy gate structures of the p-type device region, similar to removal of the spacer material over the n-type device region described with respect to FIG. 3, and leaving the silicide 134 intact on the n-type device region 106. Between FIGS. 15 and 16, the lithographic process described with respect to FIGS. 2-3 is repeated for the p-type device region 108.

FIG. 16 depicts the structure of FIG. 12 after filling all the contact openings (158, 160 and 162) with a single n-type work function metal 170. Filling the contact openings with the single n-type work function metal may be accomplished using, for example, an ALD or PVD method. The single n-type work function metal may include, for example, aluminum, and acts as both the metal of MIS and MS contacts, as well as the conductive material.

In a first aspect, disclosed above is of method of fabricating hybrid contacts with a same metal. The method includes providing a starting semiconductor structure, the structure including a semiconductor substrate, raised semiconductor structure(s) coupled to the substrate having region(s) for a n-type semiconductor device and region(s) for a p-type semiconductor device, the regions separated by isolation material, dummy gate structure(s) over each of the regions and a conformal layer of a spacer material over the starting structure. The method further includes creating a metal-insulator-semiconductor (MIS) contact for the n-type semiconductor device, and creating a metal-semiconductor (MS) contact for the p-type semiconductor device. The metal is a same metal for both contacts.

In one example, creating the MIS contact and creating the MS contact together include creating n-type epitaxy on the raised structure(s) over the region(s) for the n-type semiconductor device, creating silicide over the n-type epitaxy, creating p-type epitaxy on the raised structure(s) over the region(s) for the p-type semiconductor device, replacing the dummy gate structures with replacement gate structures, and creating contact openings to the replacement gate structures, to the silicide over the n-type epitaxy and to the p-type epitaxy. In addition, creating the MIS contact and creating the MS contact together may further include creating a blanket layer of protective material over the semiconductor structure prior to replacing the dummy gate structures and creating the contact openings. In one example, creating the blanket layer of protective material may include creating a layer of silicon nitride having a thickness of about 3 nm to about 5 nm.

In one example, creating the MIS contact and creating the MS contact together may further include, for creating the gate contact openings, creating a layer of dielectric material over the semiconductor structure, and creating openings through the layer of dielectric material to the replacement gate structures, to the silicide over the n-type epitaxy and to the p-type epitaxy.

In one example, creating the MIS contact and creating the MS contact together may further include, for creating the gate contact openings, creating silicide over the semiconductor structure except along sides of the dummy gate structures, and removing the silicide over the region(s) for the p-type semiconductor device. Creating the silicide over the semiconductor structure except along sides of the dummy gate structures may include, for example, directionally depositing the silicide using pressure vapor deposition.

In one example, creating the MIS contact and creating the MS contact together may further include, for example, filling all the contact openings with n-type work function material(s), and filling all the contact openings with conductive material(s) over the n-type work function material(s).

In one example, creating the MIS contact and creating the MS contact together may further include, for example, filling all the contact openings with a single n-type work-function metal, for example, aluminum.

In a second aspect, disclosed above is a semiconductor structure. The structure includes n-type semiconductor device(s), p-type semiconductor device(s), a metal-insulator-semiconductor (MIS) contact for the n-type semiconductor device(s), and a metal-semiconductor (MS) contact for the p-type semiconductor device(s). The metal for the MS contact is a same metal as that of the MIS contact.

In one example, the insulator of the MIS contact may include titanium oxide.

In one example, the semiconductor of the MIS and MS contacts may include epitaxial silicon germanium. The epitaxial silicon germanium may include, for example, less than about 25% germanium for the n-type device(s) and more than about 80% germanium for the p-type device(s).

In one example, the semiconductor of the MIS contact in the structure of the second aspect may include epitaxial phosphorus-doped silicon.

In one example, the metal of the MIS and the MS contacts in the structure of the second aspect may include n-type work function metal(s).

In another example, the metal of the MIS and the MS contacts, and the conductive contact material in the structure of the second aspect may all include a single n-type work function metal. The single n-type work function metal may include, for example, aluminum.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A method, comprising:
providing a starting semiconductor structure, the structure comprising a semiconductor substrate, at least one raised semiconductor structure coupled to the substrate having at least one region for a n-type semiconductor device and at least one region for a p-type semiconductor device, the regions separated by isolation material, at least one dummy gate structure over each of the regions and a conformal layer of a spacer material over the starting structure;
creating a metal-insulator-semiconductor (MIS) contact for the n-type semiconductor device; and
creating a metal-semiconductor (MS) contact for the p-type semiconductor device, wherein the metal is a same metal as the MIS contact.

2. The method of claim 1, wherein creating the MIS contact and creating the MS contact together comprise:
creating n-type epitaxy on the at least one raised structure over the at least one region for the n-type semiconductor device;
creating silicide over the n-type epitaxy;
creating p-type epitaxy on the at least one raised structure over the at least one region for the p-type semiconductor device;
replacing the dummy gate structures with replacement gate structures; and
creating contact openings to the replacement gate structures, to the silicide over the n-type epitaxy and to the p-type epitaxy.

3. The method of claim 2, further comprising creating a blanket layer of protective material over the semiconductor structure prior to the replacing and creating the contact openings.

4. The method of claim 3, wherein creating the blanket layer of protective material comprises creating a layer of silicon nitride having a thickness of about 3 nm to about 5 nm.

5. The method of claim 2, wherein creating gate contact openings comprises:
creating a layer of dielectric material over the semiconductor structure; and
creating openings through the layer of dielectric material to the replacement gate structures, to the silicide over the n-type epitaxy and to the p-type epitaxy.

6. The method of claim 2, wherein creating the silicide comprises:
creating silicide over the semiconductor structure except along sides of the dummy gate structures; and
removing the silicide over the at least one region for the p-type semiconductor device.

7. The method of claim 6, wherein creating silicide over the semiconductor structure except along sides of the dummy gate structures comprises directionally depositing the silicide using pressure vapor deposition.

8. The method of claim 2, further comprising:
filling all the contact openings with one or more n-type work function materials; and
filling all the contact openings with one or more conductive materials over the one or more n-type work function materials.

9. The method of claim 2, further comprising filling all the contact openings with aluminum.

10. A semiconductor structure, comprising:
at least one n-type semiconductor device;
at least one p-type semiconductor device;
a metal-insulator-semiconductor (MIS) contact for the n-type semiconductor device; and
a metal-semiconductor (MS) contact for the p-type semiconductor device, wherein the metal is a same metal as the MIS contact.

11. The semiconductor structure of claim 10, wherein the insulator of the MIS contact comprises titanium oxide.

12. The semiconductor structure of claim 10, wherein the semiconductor of the MIS contact and MS contact comprises epitaxial silicon germanium.

13. The semiconductor structure of claim 12, wherein the epitaxial silicon germanium comprises less than about 25% germanium for the at least one n-type device and more than about 80% for the at least one p-type device.

14. The semiconductor structure of claim 10, wherein the semiconductor of the MIS contact comprises epitaxial phosphorus-doped silicon.

15. The semiconductor structure of claim 10, wherein the metal of the MIS contact and the MS contact comprises one or more n-type work function metals.

16. The semiconductor structure of claim 10, wherein the metal of the MIS contact and the MS contact and the conductive contact material all comprise a single n-type work function metal.

17. The semiconductor structure of claim 16, wherein the single n-type work function metal comprises aluminum.
